(19) United States
(12) Patent Application Publication
(10) Pub. No.: US 2025/0137854 A1
(43) Pub. Date: May 1, 2025

(54) METHOD AND DEVICE FOR CHECKING THE PLAUSIBILITY OF A TEMPERATURE IN A COMPONENT OF AN ELECTRICAL MACHINE IN A TECHNICAL SYSTEM

(71) Applicant: Robert Bosch GmbH, Stuttgart (DE)

(72) Inventors: Christoph Woll, Gerlingen (DE); Wael Hilali, Stuttgart (DE)

(21) Appl. No.: 18/719,522

(22) PCT Filed: Oct. 24, 2022
(86) PCT No.: PCT/EP2022/079573

§ 371 Date: Jun. 13, 2024

(30) Foreign Application Priority Data
Dec. 16, 2021 (DE) 10 2021 214 526.4

(51) Int. Cl. G01K 19/00; G01K 3/10

(52) U.S. Cl. CPC G01K 19/00; G01K 3/10; G01K 2205/00

(57) ABSTRACT

The invention relates to a method for checking the plausibility of a temperature measurement of a temperature sensor (4) on a component (21, 22) of an electrical machine (2) in a technical device (1), comprising the following steps: —monitoring (S1) a current in the electrical machine (2); —upon detecting a steady-state load operation, providing (S4) a first temperature measured value of a temperature of the component (21, 22) of the electrical machine (2), the duration of the steady-state load operation, and an ambient temperature; —detecting (S7) a second temperature measured value at an end of the steady-state load operation; —determining (S8) a modelled temperature value (T_{mod}) using a data-based temperature model as a function of the first temperature measured value, the duration, and the ambient temperature, wherein the temperature model is trained to assign the first temperature measured value, the duration, and the ambient temperature to a modelled temperature value (T_{mod}); —checking the plausibility (S9) of the second temperature measured value with the modelled temperature value.

### BACKGROUND

The invention relates to electrical machines for electrical drive systems, in particular methods for checking the plausibility of a temperature measurement of a temperature sensor in a component of the electrical machine.

During the operation of electric motors, current flows in stator and/or rotor coils cause power losses that lead to the heating of electric motor components. The heat development depends, among other things, on the motor current flowing into the electric motor or the power converted in it. Overheating of electric motor components can lead to damage or destruction of coil components and can reduce the performance of the electric motor due to the impairment of the magnetic field strength (demagnetization) of hard and soft magnetic components.

The heat development of an electric motor is therefore monitored during operation and overheating is prevented by limiting the motor torque, i.e., by limiting the current consumption.

Conventional solutions provide for the arrangement of one or more temperature sensors, usually as temperature-sensitive resistors such as NTC (Negative Thermal Coefficient) sensors, on stator coils. These measure a temperature at a specific point on the stator, but this usually does not correspond to a maximum or representative temperature in the electric motor, as the position at which the maximum temperature occurs differs from the position(s) of the temperature sensors.

Temperatures in moving components of the electric motor, such as the rotor, are currently determined by means of physical modeling, which, however, cannot generally take all thermal sources or sinks into account. In addition, the modeled heat loss terms must be determined or calibrated using very complex simulation and/or test bench measurements.

Electric motors as electrical machines are currently used both as drive motors and as servomotors for vehicles, work machines, and as actuators.

Since determining the temperature of electrical machine components using a temperature sensor is essential to prevent damage or destruction of the electrical machine, it is necessary to monitor the proper functioning of the temperature sensor. Simple methods for checking the plausibility of the temperature sensor signal are already conventionally implemented, wherein in particular the monitoring of a temperature change within a certain time or implausible high or low temperature values are used for anomaly detection. Other methods for checking the plausibility of the sensor value of the temperature sensor involve monitoring a coolant temperature.

Monitoring a measured value of the temperature sensor using a virtual sensor, which can be implemented with a complete physical temperature model, is very complex and requires a high computing effort, especially if machine learning methods are used.

### SUMMARY

According to the invention, a method for checking the plausibility of a temperature measurement with a temperature sensor in a component of an electric motor as well as a device and a motor system are provided.

Further embodiments are specified in the dependent claims.

According to a first aspect, a method for checking the plausibility of a temperature measurement of a temperature sensor on a component of an electrical machine is provided, comprising the following steps:
monitoring a current in the electrical machine;
when detecting steady-state load operation, providing a first temperature measured value of a temperature of the electrical machine component, the duration of steady-state load operation, and an ambient temperature;
recording of a second temperature measured value at the end of steady-state load operation;
determining a modeled temperature value using a data-based temperature model dependent on the first temperature measured value, the duration, and the ambient temperature, wherein the temperature model is trained to associate the first temperature measured value, the duration, and the ambient temperature with a modeled temperature value;
checking the plausibility of the second temperature measured value with the modeled temperature value.

It may be necessary to check that the duration of the stationary case is sufficiently long so that a significant temperature difference can be evaluated to detect a signal drift. In particular, if an implausible temperature value occurs, this can be signaled accordingly, in particular by an optical or acoustic signal, and/or the operating mode of the electrical machine can be adjusted accordingly by reducing the power in order to prevent the component of the electrical machine from overheating.

It may be provided that a steady-state load operation is detected when a current into or out of the electrical machine is constant for a predetermined minimum duration and for a predetermined maximum duration, or does not deviate from an average value of the current during the duration by more than a predetermined tolerance amount.

To monitor a temperature sensor installed in a component of an electrical machine, such as a stator or a rotor, the above method proposes a temperature model applicable in a static operating condition of the electrical machine. In normal operation, the temperature sensor is continuously monitored and thus enables a timely power reduction or derating to avoid demagnetization of components of the electrical machine.

However, a signal drift often occurs during the service life of a temperature sensor, so that the sensor signal becomes sluggish, resulting in a deviation between a measured temperature and an actual temperature. The reverse case, where the temperature sensor signal changes more than the actual temperature, also occurs occasionally.

To check the plausibility of a temperature measurement with a temperature sensor, it is proposed to provide a temperature model that models the temperature behavior of a component of an electrical machine for a static operating case in accordance with the above method. In particular, the temperature model can describe a temperature change for a duration of a stationary state during which the electrical machine is de-energized or subjected to a constant load.

The temperature model can be implemented as a data-based model, e.g., in a control unit as software or hardware, and can model a temperature value at the end of the duration of the stationary state depending on a first measured temperature value of a current component temperature at the start of a stationary state of the electrical machine, an ambient temperature, and the duration of the stationary state. The temperature model can be trained depending on laboratory measurements of the temperature measurement at the end of the steady state duration. A temperature model modeled in this way avoids the problem of exact temperature determination using a suitable physical model based on a time integration method with dynamic and highly dynamic load phases, as the time-delayed temperature curve can only be modeled with great effort. The above temperature model therefore provides for modeling a temperature change or a temperature for the end of the duration of the stationary state only for stationary operating phases, especially in the currentless case.

The application of such a simplified temperature model makes use of the fact that in conventional operating modes of electric motors as drive or servomotors, there are always standstill phases or phases of constant load. These represent operating cases that are characterized by model-based, easily predictable behavior and can be evaluated according to the data-based temperature model. In the case of a drive motor for a motor vehicle, for example, phases in which the vehicle is stationary after an operating phase, such as at a traffic light stop or in a traffic jam, can always be used to check the plausibility of the temperature sensor. These phases occur regularly during operation, so that a corresponding regular plausibility check can be carried out.

Such standstill phases are also frequent in an electrical machine used as a servomotor in a driven machine, so that a signal drift of the temperature sensor can be detected at an early stage by regular plausibility checks.

Furthermore, the data-based temperature model can be designed to assign an electric current at the steady-state load to the modeled temperature value, wherein the modeled temperature value is determined depending on the first temperature measured value, the duration, the ambient temperature, and the constant electric current.

According to one embodiment, the detection of an implausible temperature measured value can be signaled by an optical or acoustic signal and/or the operating mode of the electrical machine can be adjusted accordingly by reducing the power in order to prevent the component of the electrical machine from overheating.

According to an alternative, the temperature model can be calculated in a control unit for the electrical machine in a technical device.

If a plausible second temperature measured value is determined, the data-based temperature model can be further trained or retrained based on the first temperature measured value, the duration, the ambient temperature, and the second temperature measured value.

The data-based temperature model can be designed as a probabilistic regression model, wherein the further training is only performed if a confidence value is determined using the data-based temperature model at a data point determined by the first temperature measured value, the duration, and the ambient temperature, which is lower than a predefined confidence threshold value.

The temperature model can therefore be calculated in a control unit for the electrical machine. In particular, if a probabilistic regression model is used as the temperature model, further training to improve the temperature model can be carried out if a confidence value resulting from the evaluation of the probabilistic regression model for an electrical machine falls below a confidence threshold.

According to another alternative, the temperature model may be calculated in a remote central processing unit that is in communication with a plurality of technical devices with the electrical machines.

In particular, if a plausible second temperature measured value is detected in one of the plurality of technical devices, the data-based temperature model can be further trained or re-trained based on the first temperature measured value, the duration, the ambient temperature, and the second temperature measured value.

It may be provided that the data-based temperature model is designed as a probabilistic regression model, wherein the further training is only carried out if a confidence value is determined using the data-based temperature model at a data point determined by the first temperature measured value, the duration, and the ambient temperature, which is lower than a predetermined confidence threshold value.

The temperature model can therefore also be implemented externally to the technical device, for example in a cloud. In particular, when implemented in an external central unit (cloud), the temperature model can be further trained using additional operating points of a large number of similar technical systems with electrical machines of identical type (design). In particular, if a probabilistic regression model is used as the temperature model, further training to improve the temperature model can be carried out if a confidence value resulting from the evaluation of the probabilistic regression model for an electrical machine falls below a confidence threshold.

### BRIEF DESCRIPTION OF THE DRAWINGS

Embodiments are explained in more detail below with reference to the accompanying drawings. Shown are:

FIG. 1 a schematic representation of a technical device with an electrical machine and a control unit;

FIG. 2 a schematic representation of an electrical machine with a temperature sensor for temperature monitoring;

FIG. 3 a flowchart illustrating a method for operating the technical device;

FIG. 4 a diagram illustrating the function of the temperature model; and

FIG. 5 a system with a plurality of similar technical devices and a central unit for carrying out the method for checking the plausibility of a temperature measurement by a temperature sensor in an electrical machine.

### DETAILED DESCRIPTION

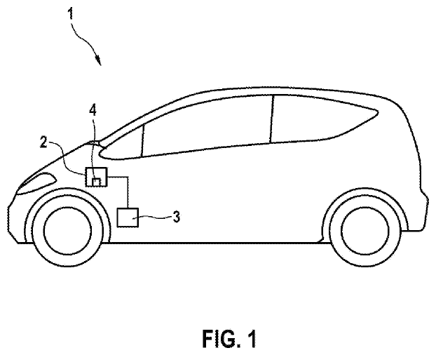

FIG. 1 schematically shows a motor vehicle 1 as an example of a technical device with an electrical machine 2 as the drive motor, which is operated via a control unit 3. The electrical machine 2 contains a temperature sensor 4 to monitor the temperature of the electrical machine 2. Using a method implemented in the control unit 3 to check the plausibility of a component temperature of a component of the electrical machine with a temperature model, the measured temperature value is to be compared with a modeled temperature value and a corresponding error is to be signaled in the event of a deviation.

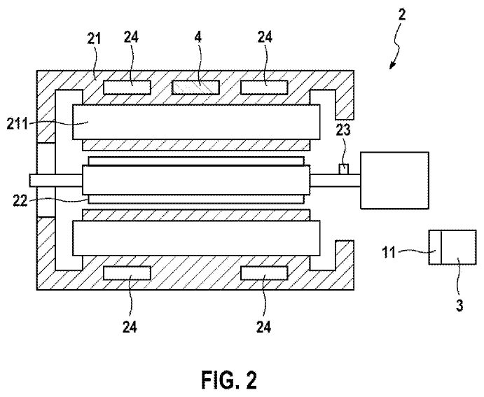

FIG. 2 shows a schematic cross-sectional view of an electrical machine 2 as part of a drive system. The electrical machine 2 has a stator 21 and a rotor 22 mounted on a shaft, which are the components of the electrical machine. Furthermore, the stator 21 can be provided with stator coils 211, which can be electrically controlled via phase voltages and phase currents. In alternative embodiments, rotor coils and both stator and rotor coils can also be provided.

The electrical machine 2 is controlled with the aid of the control unit 4, which provides for the control of the electrical machine 2 by applying phase voltages to the stator coil 211 in accordance with a commutation pattern. The control unit 4 can therefore also comprise a power driver circuit 5 in the form of a B6 bridge circuit or similar in a manner known per se.

Furthermore, the rotor 22 can be coupled to a position sensor 23, which can detect a rotor position of the rotor with respect to the arrangement of the stator coils 211.

The control unit 4 operates the electrical machine 2 in a known manner by specifying the phase voltages in order to set certain phase currents so that a specified motor torque is provided. When the phase currents are applied, power is converted in the electrical machine 2, which can lead to the components of the electrical machine 2 heating up. Heating occurs unevenly in the components.

Coolant ducts 24 are provided in the stator 21 for the passage of coolant. The coolant is fed through the coolant ducts 24 at a flow rate known in the control unit 3.

The control unit 4 can also be designed to operate a temperature model for monitoring a measured temperature value of the temperature sensor 4 in real time. It is necessary to monitor the function of the temperature sensor 4, as improper function can lead to undetected overheating of components of the electrical machine 2.

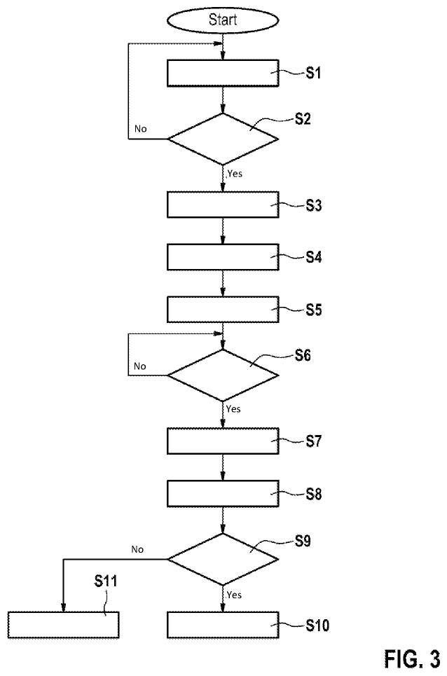

FIG. 3 shows a flow chart that illustrates the method for checking the plausibility of a temperature measurement with a temperature sensor in an electrical machine in more detail. The method can be implemented, for example, in the control unit 3 of the vehicle shown in FIG. 1 as an example of the technical device.

In step S1, the motor current of the electrical machine is continuously measured and monitored.

In step S2, it is checked whether the electrical machine 2 is de-energized or is operated with a constant load, i.e., a constant motor current. If this is the case (alternative: Yes), the method is continued with step S3, otherwise (alternative: No) the system jumps back to step S1.

In step S3, the system first waits until a steady state has been reached. For example, the waiting time can be between 0 and 2 s, preferably 1 s.

In step S4, a temperature measurement is carried out and a resulting first temperature measured value is temporarily stored.

Furthermore, an ambient temperature is recorded and temporarily stored in step S5.

In a subsequent step S6, it is checked whether the stationary operation has changed due to an interim change in the current consumption of the electrical machine or whether a specified maximum duration has elapsed since the first temperature measured value was recorded. If this is the case (alternative: Yes), the method is continued with step S7, otherwise (alternative: No), the system jumps back to step S6.

In step S7, a second temperature measured value is recorded using the temperature sensor 4 in a second temperature measurement and a duration between the recording of the temperature measured values is determined as the duration of the stationary phase and temporarily stored.

In step S8, a model evaluation is now carried out with the temperature model, which is trained to assign the first temperature measured value, the ambient temperature, and the duration of the stationary phase to a modeled temperature value.

The temperature model comprises a data-based model and can be designed in particular as a probabilistic regression model, e.g., in the form of a Gaussian process model. A probabilistic regression model has the advantage that in addition to the model output, a confidence value can also be output to indicate the reliability of the model.

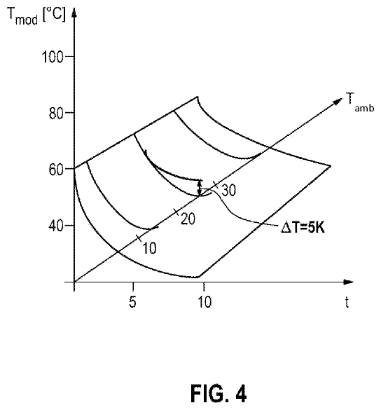

An example of the function of the data-based temperature model is shown in FIG. 4. The dependence of the modeled temperature value T_{mod} on the duration t of the stationary state and the ambient temperature T_{amb} can be seen with an exemplary first temperature measured value T of 60° C. In further embodiments, the temperature model can also take into account a constant load in the form of a motor current as a further input dimension.

In a subsequent step S9, the modeled temperature value T_{mod} is compared with the second temperature measured value T2 measured at the end of the duration of stationary operation.

If a temperature difference of preferably more than a predefined tolerance threshold amount (of, e.g., 1° C.) is detected (alternative: Yes), a corresponding error message is signaled in step S10. This can be issued to the driver of the vehicle via an optical or acoustic signal or a power reduction or power limitation can be provided for the electric motor.

If no temperature difference is detected (alternative: No), the method continues with step S11.

In step S11, the corresponding query of the temperature model from the first temperature measured value, the duration of the stationary operation, the ambient temperature, and the second temperature value at the end of the duration can be stored or used as a training data set for further training of the data-based temperature model. In particular, it may be provided that the training data set is only used for further training of the temperature model if the temperature model has a confidence value below a predetermined confidence threshold value at the relevant evaluation point from the first temperature measured value, the duration of stationary operation, and the ambient temperature. In this way, the temperature model can be successively improved.

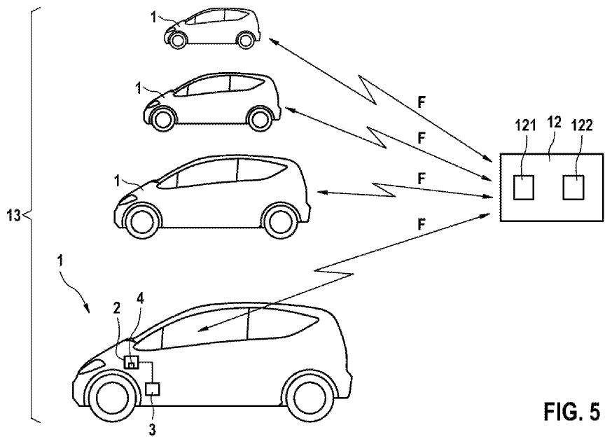

FIG. 5 shows a further embodiment of a system in which a plurality of vehicles 1 in a vehicle fleet 13 transmit the first and second temperature measured values, the duration, and the ambient temperature to a central unit 12 in the form of operating data F as soon as these are available from a measurement. The central unit 12 has a data processing unit 121, in which the evaluation of the temperature model can be carried out, and a database 122 for storing data points, model parameters, states, and the like.

The system is used to collect fleet data in the central unit 12 and to check the plausibility of a second temperature measured value and create the data-based temperature model. For this purpose, the corresponding operating variables are transmitted from each of the vehicles 1 to the central unit 12 when a stationary state has been detected. By querying the temperature model based on a transmission of the first temperature value, the duration of stationary operation, and the ambient temperature to the central unit 12, the corresponding modeled temperature value can be transmitted back to the vehicle in question, so that the plausibility check of the second temperature measured value can be carried out in the vehicle in the manner described above.

Furthermore, if the second temperature value at the end of the stationary duration is also transmitted to the central unit 12 as described above, a corresponding plausibility check can also be carried out in the central unit 12. If it is determined that the corresponding temperature sensor in the transmitting vehicle is not functioning properly, this can be signaled accordingly and communicated to the vehicle. However, if it is determined that the corresponding temperature sensor is functioning properly, the recorded data set from the variables of the first temperature value, the duration of steady-state operation, and the ambient temperature can be used as a training data set for further training of the temperature model in the central processing unit 12. In this way, a large number of similar devices or vehicles can be used to further develop the temperature model.

1. A method for checking the plausibility of a temperature measurement of a temperature sensor (4) on a component (21, 22) of an electrical machine (2) in a technical device (1), comprising the following steps:
monitoring (S1), via an electronic controller, a current in the electrical machine (2);
upon detecting a steady-state load operation, providing (S4), via a temperature sensor, a first temperature measured value of a temperature of the component (21, 22) of the electrical machine (2), the duration of the steady-state load operation, and an ambient temperature;
detection (S7) of a second temperature measured value at the end of steady-state load operation;
determining (S8), via the electronic controller, a modeled temperature value (T_{mod}) using a data-based temperature model dependent on the first temperature measured value, the duration, and the ambient temperature, wherein the temperature model is trained to associate the first temperature measured value, the duration and the ambient temperature with a modeled temperature value (T_{mod});
checking, via the electronic controller, the plausibility (S9) of the second temperature measured value with the modeled temperature value.

2. The method according to claim 1, wherein a steady-state load operation is detected when a current into or out of the electrical machine (2) is constant for a predetermined minimum duration and for a predetermined maximum duration or does not deviate from an average value of the current during the duration by more than a predetermined tolerance amount.

3. A method according to claim 1, wherein the data-based temperature model is further configured to assign an electric current at the steady-state load to the modeled temperature value (T_{mod}), wherein the modeled temperature value (T_{mod}) is determined depending on the first temperature measured value, the duration, the ambient temperature, and the constant electric current.

4. A method according to claim 1, wherein the detection of an implausible temperature measured value is signaled by an optical or acoustic signal and/or the operating mode of the electrical machine (2) is adapted accordingly by reducing the power in order to avoid overheating of the component (21, 22) of the electrical machine (2).

5. A method according to claim 1, wherein the temperature model is calculated in a control unit (3) for the electrical machine (2) in a technical device (1).

6. The method according to claim 5, wherein when a plausible second temperature measured value is determined, the data-based temperature model is further trained or retrained based on the first temperature measured value, the duration, the ambient temperature, and the second temperature measured value.

7. The method according to claim 6, wherein the data-based temperature model is designed as a probabilistic regression model, wherein the further training is only performed if a confidence value is determined at a data point determined by the first temperature measured value, the duration, and the ambient temperature using the data-based temperature model which is less than a predetermined confidence threshold value.

8. A method according to claim 1, wherein the temperature model is calculated in a central unit (12) remote from the device, which is in communication with a plurality of technical devices (1) with the electrical machines.

9. The method according to claim 8, wherein upon detecting a plausible second temperature measured value in one of the plurality of technical devices (1), the data-based temperature model is further trained or re-trained based on the first temperature measured value, the duration, the ambient temperature, and the second temperature measured value.

10. The method according to claim 9, wherein the data-based temperature model is designed as a probabilistic regression model, wherein the further training is only performed if a confidence value is determined at a data point determined by the first temperature measured value, the duration, and the ambient temperature using the data-based temperature model, which is less than a predetermined confidence threshold value.

11. An electronic controller configured to check the plausibility of a temperature measurement of a temperature sensor (4) on a component (21, 22) of an electrical machine (2) in a technical device (1), by:
monitoring (S1) a current in the electrical machine (2);
upon detecting a steady-state load operation, providing (S4) a first temperature measured value of a temperature of the component (21, 22) of the electrical machine (2), the duration of the steady-state load operation, and an ambient temperature;
detecting (S7) a second temperature measured value at the end of steady-state load operation;
determining (S8) a modeled temperature value (T_{mod}) using a data-based temperature model dependent on the first temperature measured value, the duration, and the ambient temperature, wherein the temperature model is trained to associate the first temperature measured value, the duration and the ambient temperature with a modeled temperature value (T_{mod}); and
checking, via the electronic controller, the plausibility (S9) of the second temperature measured value with the modeled temperature value.

12. (canceled)

13. A non-transitory, computer-readable medium comprising instructions which, when executed by a computer, cause the computer to check the plausibility of a temperature measurement of a temperature sensor (4) on a component (21, 22) of an electrical machine (2) in a technical device (1), by:
monitoring (S1) a current in the electrical machine (2);
upon detecting a steady-state load operation, providing (S4) a first temperature measured value of a temperature of the component (21, 22) of the electrical machine (2), the duration of the steady-state load operation, and an ambient temperature;
detecting (S7) a second temperature measured value at the end of steady-state load operation;
determining (S8) a modeled temperature value (T_{mod}) using a data-based temperature model dependent on the first temperature measured value, the duration, and the ambient temperature, wherein the temperature model is trained to associate the first temperature measured value, the duration and the ambient temperature with a modeled temperature value (T_{mod}); and
checking, via the electronic controller, the plausibility (S9) of the second temperature measured value with the modeled temperature value.
